(19) United States
(12) Patent Application Publication
(10) Pub. No.: US 2026/0246483 A1
(43) Pub. Date: Aug. 20, 2026

(54) CURRENT-ACCELERATED VOLTAGE TRANSITION IN A WIRELESS COMMUNICATION CIRCUIT

(71) Applicant: Qorvo US, Inc., Greensboro, NC (US)

(72) Inventors: Nadim Khlat, Cugnaux (FR); Baker Scott, San Jose, CA (US); George Maxim, Saratoga, CA (US); Woo Yong Lee, Chapel Hill, NC (US)

(21) Appl. No.: 18/996,422

(22) PCT Filed: Sep. 6, 2023
(86) PCT No.: PCT/US2023/032065

§ 371 Date: Jan. 17, 2025

Related U.S. Application Data
(60) Provisional application No. 63/408,932, filed on Sep. 22, 2022.

(51) Int. Cl. H04B 1/04; H03F 1/02; H03F 3/24

(52) U.S. Cl. CPC H04B 1/04; H03F 1/0233; H03F 3/245; H03F 2200/105; H03F 2200/451; H04B 2001/0408

(57) ABSTRACT

Current-accelerated voltage transition in a wireless communication circuit is disclosed. The wireless communication circuit includes a power management integrated circuit (PMIC) configured to generate a voltage, such as an average power tracking (APT) voltage, for amplifying a radio frequency (RF) signal in multiple continuous voltage modulation intervals. In a non-limiting example, each of the voltage modulation intervals can be an orthogonal frequency division multiplexing (OFDM) symbol or a timeslot with multiple OFDM symbols. According to embodiments disclosed herein, the PMIC can generate an acceleration current with an appropriate polarity to accelerate a transition of the voltage quickly between consecutive voltage modulation intervals. By supporting the current-accelerated voltage transition, the wireless transmission circuit can enable fast voltage adaptation to thereby improve operating efficiency of a power amplifier circuit.

### RELATED APPLICATIONS

This application claims the benefit of U.S. provisional patent application Ser. No. 63/408,932, filed on Sep. 22, 2022, the disclosures of which are hereby incorporated herein by reference in their entireties.

### FIELD OF THE DISCLOSURE

The technology of the disclosure relates generally to accelerating a voltage transition between two adjacent ones of multiple voltage modulation intervals, such as orthogonal frequency division multiplexing (OFDM) symbols and timeslots.

### BACKGROUND

Fifth generation (5G) and 5G new radio (NR) (5G-NR) have been widely regarded as the next generation of wireless communication technology beyond the current third generation (3G) and fourth generation (4G) technologies. In this regard, a wireless communication device capable of supporting 5G and/or 5G-NR is expected to achieve higher data rates, improved coverage range, enhanced signaling efficiency, and reduced latency.

Downlink and uplink transmissions in 5G and 5G-NR systems are based on orthogonal frequency division multiplexing (OFDM). In an OFDM based system, physical radio resources are divided into a number of subcarriers in a frequency domain and a number of OFDM symbols in a time domain. The subcarriers are orthogonally separated from each other by a subcarrier spacing (SCS). The OFDM symbols are separated from each other by a cyclic prefix (CP), which acts as a guard band to help overcome inter-symbol interference (ISI) between the OFDM symbols.

A radio frequency (RF) signal communicated in the OFDM based system is often modulated into multiple subcarriers in the frequency domain and multiple OFDM symbols in the time domain. The multiple subcarriers occupied by the RF signal collectively define a modulation bandwidth of the RF signal. The multiple OFDM symbols can be further organized into multiple timeslots and modulated based on a certain modulation and coding scheme (MCS) to carry control signals and/or data payloads. In 5G and 5G-NR systems, the RF signal is typically modulated with a high modulation bandwidth in excess of 200 MHz.

The duration of a timeslot is determined by the number of OFDM symbols included therein and the duration of each OFDM symbol. The duration of an OFDM symbol depends on the SCS and the modulation bandwidth. The table below (Table 1) provides some OFDM symbol durations, as defined by 3G partnership project (3GPP) standards for various SCSs and modulation bandwidths. Notably, the higher the modulation bandwidth is, the shorter the OFDM symbol duration will be. For example, when the SCS is 120 KHz and the modulation bandwidth is 400 MHz, the OFDM symbol duration is 8.93 μs.

TABLE 1

| | | OFDM Symbol | Modulation |
|---|---|---|---|
| SCS | CP | Duration | Bandwidth |
| (KHz) | (μs) | (μs) | (MHz) |
| 15 | 4.69 | 71.43 | 50 |
| 30 | 2.34 | 35.71 | 100 |
| 60 | 1.17 | 17.86 | 200 |
| 120 | 0.59 | 8.93 | 400 |

The RF signal is typically modulated with a time-variant power that changes between OFDM symbols and/or timeslots. Such inter-symbol and/or inter-timeslot power variation creates a unique challenge for a power management integrated circuit (PMIC) that is configured to supply a voltage to a power amplifier circuit to amplify the RF signal. For example, if the time-variant power of the RF signal increases from one power level in one OFDM symbol to another power level in a succeeding OFDM symbol, the PMIC must increase the voltage as quick as possible to avoid amplitude distortion in the RF signal. Should the time-variant power of the RF signal decrease from one power level in one OFDM symbol to another power level in a succeeding OFDM symbol, the PMIC must reduce the voltage as quickly as possible to reduce energy waste and prolong battery life. Hence, it is desirable to accelerate the voltage transition in accordance with the time-variant power of the RF signal.

### SUMMARY

Embodiments of the disclosure relate to a current-accelerated voltage transition in a wireless communication circuit. The wireless communication circuit includes a power management integrated circuit (PMIC) configured to generate a voltage, such as an average power tracking (APT) voltage, for amplifying a radio frequency (RF) signal in multiple continuous voltage modulation intervals. In a non-limiting example, each of the voltage modulation intervals can be an orthogonal frequency division multiplexing (OFDM) symbol or a timeslot with multiple OFDM symbols. According to embodiments disclosed herein, the PMIC can generate an acceleration current with appropriate polarity to accelerate the transition of the voltage quickly between consecutive voltage modulation intervals. By supporting the current-accelerated voltage transition, the wireless transmission circuit can enable fast voltage adaptation to thereby improve operating efficiency of a power amplifier circuit.

In one aspect, a PMIC is provided. The PMIC includes a voltage modulation circuit. The voltage modulation circuit is configured to generate a voltage in multiple voltage modulation intervals. The PMIC also includes an acceleration control circuit. The acceleration control circuit is configured to determine that the voltage is transitioning from a present voltage level in a present voltage modulation interval among the multiple voltage modulation intervals to a future voltage level in a future voltage modulation interval immediately succeeding the present voltage modulation interval among the multiple voltage modulation intervals. The acceleration control circuit is also configured to provide an acceleration current in a selected polarity to the voltage modulation circuit to thereby cause the voltage to transition from the present voltage level to the future voltage level within a voltage transition interval between the present voltage modulation interval and the future voltage modulation interval.

In another aspect, a wireless communication circuit is provided. The wireless communication circuit includes a PMIC. The PMIC includes a voltage modulation circuit. The voltage modulation circuit is configured to generate a voltage in multiple voltage modulation intervals. The PMIC also includes an acceleration control circuit. The acceleration control circuit is configured to determine that the voltage is transitioning from a present voltage level in a present voltage modulation interval among the multiple voltage modulation intervals to a future voltage level in a future voltage modulation interval immediately succeeding the present voltage modulation interval among the multiple voltage modulation intervals. The acceleration control circuit is also configured to provide an acceleration current in a selected polarity to the voltage modulation circuit to thereby cause the voltage to transition from the present voltage level to the future voltage level within a voltage transition interval between the present voltage modulation interval and the future voltage modulation interval.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 illustrates an exemplary timeslot(s) as widely supported in a fifth generation (5G) or a 5G new-radio (5G-NR) system for modulating a radio frequency (RF) signal;

FIG. 2 is a schematic diagram of an exemplary wireless communication circuit wherein a power management integrated circuit (PMIC) is configured according to various embodiments of the present disclosure to support a current-accelerated transition of a voltage supplied to a power amplifier circuit for amplifying a radio frequency (RF) signal;

FIGS. 3 and 4 are graphic diagrams providing exemplary illustrations of some current-accelerated voltage transition scenarios that are supported by the PMIC in FIG. 2;

FIG. 5 is a schematic diagram of an exemplary analog acceleration control circuit provided in the PMIC in FIG. 2 and configured according to one embodiment of the present disclosure;

FIG. 6 is a schematic diagram of an exemplary digital acceleration control circuit provided in the PMIC in FIG. 2 and configured according to one embodiment of the present disclosure; and

FIG. 7 is a schematic diagram of an exemplary user element wherein the wireless communication circuit of FIG. 2 can be provided.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments of the disclosure relate to a current-accelerated voltage transition in a wireless communication circuit. The wireless communication circuit includes a power management integrated circuit (PMIC) configured to generate a voltage, such as an average power tracking (APT) voltage, for amplifying a radio frequency (RF) signal in multiple continuous voltage modulation intervals. In a non-limiting example, each of the voltage modulation intervals can be an orthogonal frequency division multiplexing (OFDM) symbol or a timeslot with multiple OFDM symbols. According to embodiments disclosed herein, the PMIC can generate an acceleration current with appropriate polarity to accelerate the transition of the voltage quickly between consecutive voltage modulation intervals. By supporting the current-accelerated voltage transition, the wireless transmission circuit can enable fast voltage adaptation to thereby improve operating efficiency of a power amplifier circuit.

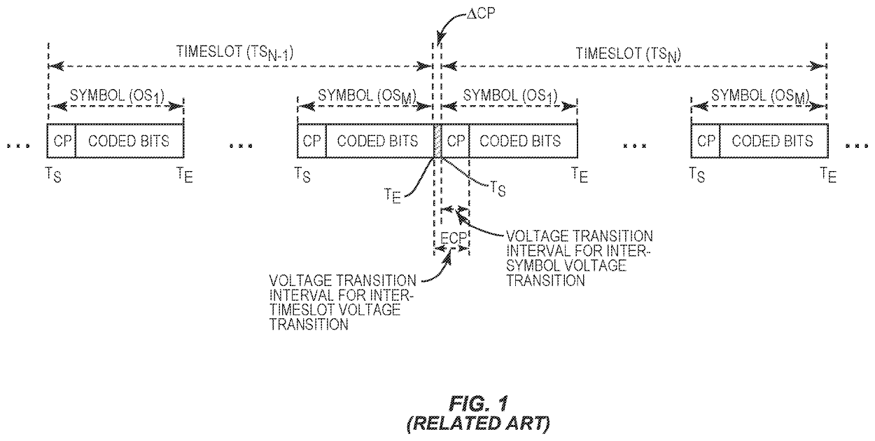

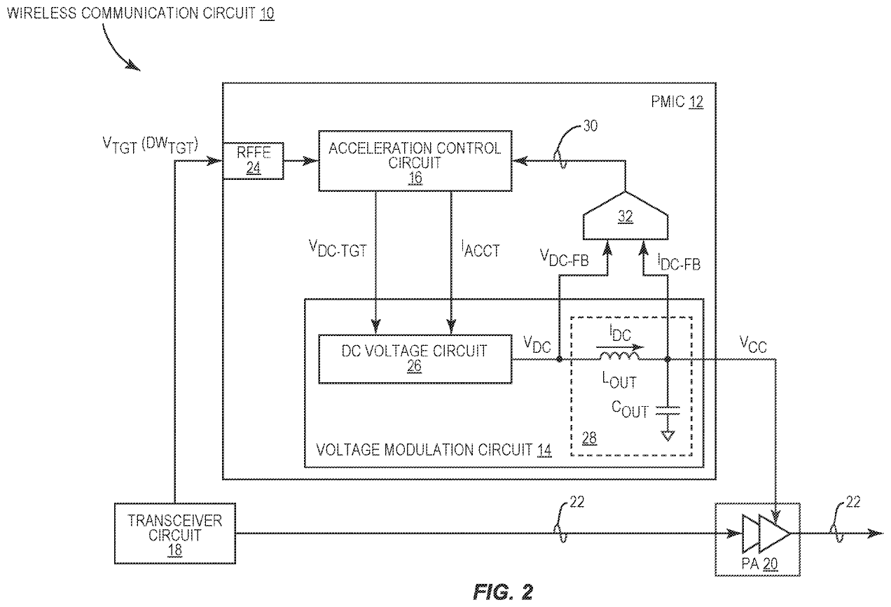

Before discussing the current-accelerated voltage transition according to the present disclosure, starting at FIG. 2, an overview of orthogonal frequency division multiplexing (OFDM) symbols and timeslots, which can be used to define durations of voltage modulation intervals, is first provided with reference to FIG. 1.

FIG. 1 illustrates a pair of consecutive timeslots TS_{N-1}, TS_{N}, each of which includes multiple OFDM symbols OS₁-OS_{M}. As previously shown in Table 1, each of the OFDM symbols OS₁-OS_{M} has a symbol duration that depends on the subcarrier spacing (SCS). Each of the OFDM symbols OS₁-OS_{M} is bound by a respective start time T_{S} and a respective end time T_{E} and includes a cyclic prefix (CP) and multiple coded bits. As shown in Table 1, the CP duration will be set once the SCS is chosen. Likewise, the duration of the timeslots TS_{N-1}, TS_{N} is determined by the duration of the OFDM symbols OS₁-OS_{M}. In this regard, the duration of the timeslots TS_{N-1}, TS_{N} also depends on the SCS.

The timeslots TS_{N-1} and T_{N} are further separated by an extra CP (ΔCP) located between the end time T_{E} of the last OFDM symbol OS_{M} in the preceding timeslot TS_{N-1} and the start time Ts of the first OFDM symbol OS₁ in the succeeding timeslot TS_{N}. The extra CP (ΔCP) and the CP of the first OFDM symbol OS₁ in the succeeding timeslot TS_{N} collectively provide an extended CP (ECP) (ECP=ΔCP+CP) between the preceding timeslot TS_{N-1} and the succeeding timeslot TS_{N}. In context of the present disclosure, the duration of each of the OFDM symbols OS₁-OS_{M} and the duration of each of the timeslots TS_{N-1}, TS_{N} can both be referred to as a voltage modulation interval, depending on whether an average power tracking (APT) voltage is modulated on an inter-symbol or an inter-timeslot basis.

Specifically, when the APT voltage is adapted between each of the OFDM symbols OS₁-OS_{M} in each of the timeslots TS_{N-1}, TS_{N}, the voltage modulation interval (also referred to as “inter-symbol voltage modulation interval”) corresponds to the duration of each of the OFDM symbols OS₁-OS_{M}. In this regard, the APT voltage transition (increase or decrease) between consecutive ones of the OFDM symbols OS₁-OS_{M} must be completed within the CP in each of the OFDM symbols OS₁-OS_{M}. Accordingly, the CP in each of the OFDM symbols OS₁-OS_{M} defines a voltage transition interval (also referred to as “inter-symbol voltage transition interval”) for completing an inter-symbol voltage transition.

In contrast, when the APT voltage is adapted between each of the timeslots TS_{N-1}, TS_{N}, the voltage modulation interval (also referred to as “inter-timeslot voltage modulation interval”) corresponds to the duration of each of the timeslots TS_{N-1}, TS_{N}. In this regard, the APT voltage transition (increase or decrease) must be completed within the extended CP (ECP) between the preceding timeslot TS_{N-1} and the succeeding timeslot TS_{N}. Accordingly, the extended CP (ECP) defines the voltage transition interval (also referred to as “inter-time voltage transition interval”) for inter-timeslot voltage transition.

FIG. 2 is a schematic diagram of an exemplary wireless communication circuit 10 wherein a PMIC 12 can be configured according to various embodiments of the present disclosure to adapt a voltage V_{CC} (e.g., an APT voltage) on inter-symbol and/or inter-timeslot basis. Herein, the PMIC 12 includes a voltage modulation circuit 14 and an acceleration control circuit 16. The voltage modulation circuit 14 is configured to generate the voltage V_{CC} in multiple voltage modulation intervals, such as multiple inter-symbol voltage modulation intervals or multiple inter-timeslot voltage modulation intervals.

In a non-limiting example, the voltage modulation circuit 14 can be configured to adapt the voltage V_{CC} on an inter-symbol basis when the SCS is lower than 60 KHz. Accordingly, the voltage modulation circuit 14 is required to transition the voltage V_{CC} from a present voltage level in a present one of the inter-symbol voltage modulation intervals to a future voltage level in a future one of the inter-symbol voltage modulation intervals within the inter-symbol voltage transition interval.

In contrast, the voltage modulation circuit 14 can be configured to adapt the voltage V_{CC} on an inter-timeslot basis when the SCS is higher than or equal to 60 KHz. Accordingly, the voltage modulation circuit 14 is required to transition the voltage V_{CC} from the present voltage level in the present one of the inter-timeslot voltage modulation intervals to the future voltage level in the future one of the inter-timeslot voltage modulation intervals within the inter-timeslot voltage transition interval.

To ensure that the voltage modulation circuit 14 can change the voltage V_{CC} from the present voltage level to the future voltage level within the inter-symbol voltage transition interval and the inter-timeslot voltage transition interval, the acceleration control circuit 16 is configured to provide an acceleration current I_{ACCT} in a selected polarity (positive polarity or negative polarity) to the voltage modulation circuit 14. As described in detail below, the acceleration current I_{ACCT} can cause the voltage modulation circuit 14 to transition the voltage V_{CC} from the present voltage level to the future voltage level within the voltage transition interval between the present voltage modulation interval and the future voltage modulation interval. By using a current-accelerated voltage transition, as opposed to a voltage-accelerated voltage transition, the PMIC 12 can adapt the voltage V_{CC} within a stringent voltage transition interval (e.g., <2 μs) and across a wider modulation bandwidth (e.g., >200 MHz).

In an embodiment, the wireless communication circuit 10 further includes a transceiver circuit 18 and a power amplifier circuit 20. The transceiver circuit 18 is configured to generate and provide an RF signal 22 to the power amplifier circuit 20, which will amplify the RF signal 22 in each of the voltage modulation intervals based on the voltage V_{CC} supplied by the PMIC 12.

The transceiver circuit 18 is also configured to generate a target voltage V_{TGT} to indicate a respective voltage level of the voltage V_{CC} in each of the voltage modulation intervals. In an embodiment, the transceiver circuit 18 may generate a respective digital word DW_{TGT} indicating the respective target voltage V_{TGT} for each of the voltage modulation intervals and provide the respective digital word DW_{TGT} to the acceleration control circuit 16 over an RF frontend (RFFE) interface 24.

In an embodiment, the voltage modulation circuit 14 includes a direct-current (DC) voltage circuit 26 and an inductor-capacitor (LC) circuit 28. The DC voltage circuit 26 is configured to generate a DC voltage V_{DC} (a.k.a. switching voltage) in each of the voltage modulation intervals. In a non-limiting example, the DC voltage circuit 26 can be a DC-DC voltage converter that adapts the DC voltage V_{DC} based on a DC target voltage V_{DC-TGT}. According to an embodiment of the present disclosure, the acceleration control circuit 16 is also configured to determine the DC target voltage V_{DC-TGT} based on the target voltage V_{TGT} received from the transceiver circuit 18.

The LC circuit 28 includes an output inductor L_{OUT} and an output capacitor C_{OUT}. The output inductor L_{OUT} is configured to induce a DC current I_{DC} in each of the voltage modulation intervals based on the DC voltage V_{DC}. The DC current I_{DC} can cause the output capacitor Cour to be charged or discharged to thereby modulate the voltage V_{CC} in each of the voltage modulation intervals.

Herein, the acceleration control circuit 16 is configured to generate the acceleration circuit I_{ACCT} with a positive polarity when the voltage V_{CC} is increasing from the present voltage level to the future voltage level. As such, the acceleration circuit I_{ACCT} can supplement the DC voltage I_{DC} to charge the load capacitor Cour quickly. In contrast, the acceleration control circuit 16 is configured to generate the acceleration circuit I_{ACCT} with a negative polarity when the voltage V_{CC} is decreasing from the present voltage level to the future voltage level. As such, the acceleration circuit I_{ACCT} can reduce the DC voltage I_{DC} to discharge the load capacitor Cour quickly.

In an embodiment, the PMIC 12 includes a feedback loop 32 that generates a feedback signal 30 based on feedback of the DC voltage V_{DC} (denoted as V_{DC-FB}) and a feedback of the DC current I_{DC} (denoted as I_{DC-FB}). The acceleration control circuit 16 is configured to determine an amount and polarity of the acceleration current I_{ACCT} based on a feedback signal 30 and the target voltage V_{TGT}.

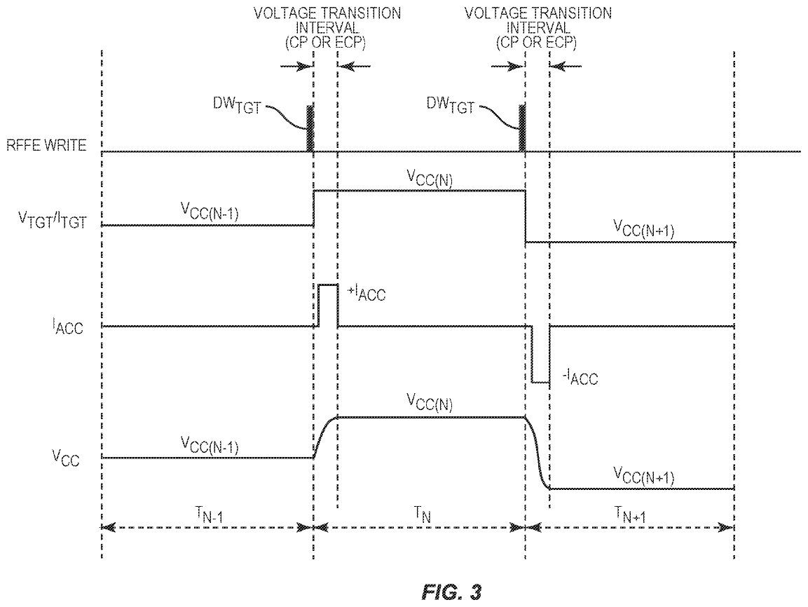

FIG. 3 is a graphic diagram illustrating an exemplary current-accelerated voltage transition scenario during three consecutive voltage modulation intervals T_{N-1}, T_{N}, T_{N+1}. Herein, each of the voltage modulation intervals T_{N-1}, T_{N}, T_{N+1} can be any of the OFDM symbols OS₁-OS_{M} or any of the timeslots TS_{N-1}, TS_{N}, as illustrated in FIG. 1. Notably, when the voltage modulation intervals T_{N-1}, T_{N}, T_{N+1} correspond to three consecutive OFDM symbols, the voltage transition interval illustrated herein will correspond to the CP in each OFDM symbol. In contrast, when the voltage modulation intervals T_{N-1}, T_{N}, T_{N+1} correspond to three consecutive timeslots, the voltage transition interval illustrated herein will correspond to the ECP in between each pair of the timeslots. In this regard, the current-accelerated voltage transition scenario described herein is generally applicable to both the inter-symbol voltage transition and the inter-timeslot voltage transition.

As previously mentioned in FIG. 2, the transceiver circuit 18 can provide a respective digital word DW_{TGT} to indicate a respective target voltage V_{TGT} in each of the voltage modulation intervals T_{N-1}, T_{N}, T_{N+1}. In an embodiment, the transceiver circuit 18 may send the digital word DW_{TGT} prior to the start of each of the voltage modulation intervals T_{N-1}, T_{N}, T_{N+1}. In another embodiment, the transceiver circuit 18 may send the digital word DW_{TGT} at the start of each of the voltage modulation intervals T_{N-1}, T_{N}, T_{N+1}.

Accordingly, the acceleration control circuit 16 can generate the amount and the polarity of the acceleration current I_{ACCT} based on the target voltage V_{TGT} and the feedback signal 30. As an example, the acceleration control circuit 16 may receive the digital word DW_{TGT} that indicates the voltage V_{CC} will increase from a present voltage level V_{CC(N-1)} in the present voltage modulation interval T_{N-1} to a future voltage level V_{CC(N)} in the future voltage modulation interval T_{N} immediately succeeding the present voltage modulation interval T_{N-1}. Accordingly, the acceleration control circuit 16 will provide a positive acceleration current +I_{ACCT} to help increase the voltage V_{CC} from the present voltage level V_{CC(N-1)} to the future voltage level V_{CC(N)} within the voltage transition interval in the voltage modulation interval T_{N}.

In another example, the acceleration control circuit 16 may receive the digital word DW_{TGT} that indicates the voltage V_{CC} will decrease from a present voltage level V_{CC(N)} in the present voltage modulation interval T_{N} to a future voltage level V_{CC(N+1)} in the future voltage modulation interval T_{N+1} immediately succeeding the present voltage modulation interval T_{N}. Accordingly, the acceleration control circuit 16 will provide a negative acceleration current −I_{ACCT} to help decrease the voltage V_{CC} from the present voltage level V_{CC(N)} to the future voltage level V_{CC(N+1)} within the voltage transition interval in the voltage modulation interval T_{N+1}.

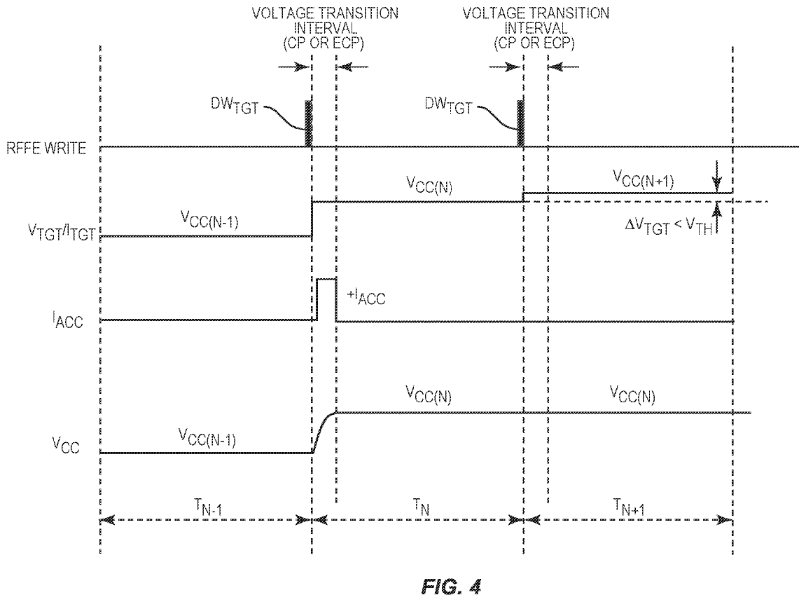

In an embodiment, the acceleration control circuit 16 may be configured to only generate the acceleration current I_{ACCT} when a voltage change between two consecutive voltage modulation intervals is greater than a defined threshold. FIG. 4 is a graphic diagram providing an exemplary illustration of such a current-accelerated voltage transition scenario during the voltage modulation intervals T_{N-1}, T_{N}, T_{N+}.

As an example, the acceleration control circuit 16 may receive the digital word DW_{TGT} that indicates the voltage V_{CC} will increase from a present voltage level V_{CC(N)} in the present voltage modulation interval T_{N} to a future voltage level V_{CC(N+1)} in the future voltage modulation interval T_{N+1} immediately succeeding the present voltage modulation interval T_{N}. The acceleration control circuit 16 may further determine that a difference (ΔV_{TGT}) between the present voltage level and the future voltage level is smaller than a defined threshold VTH. Accordingly, the acceleration control circuit 16 will not generate and provide the acceleration current I_{ACCT} to the voltage modulation circuit 14. In this regard, in absence of the acceleration current I_{ACCT}, the voltage modulation circuit 14 will maintain the present voltage level V_{CC(N)} in the future voltage modulation interval T_{N+1}.

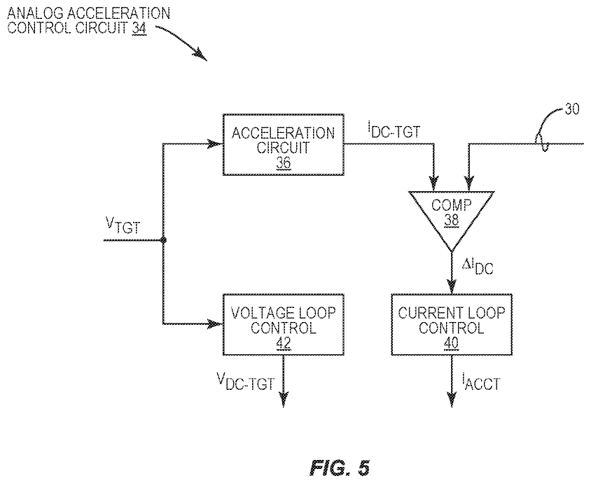

In one embodiment, the acceleration control circuit 16 in FIG. 2 can be implemented as an analog acceleration control circuit. In this regard, FIG. 5 is a schematic diagram of an exemplary analog acceleration control circuit 34 that can function as the acceleration control circuit 16 in the PMIC 12 in FIG. 2. Common elements between FIGS. 2 and 5 are shown therein with common element numbers and will not be re-described herein.

Herein, the analog acceleration control circuit 34 includes an acceleration circuit 36, a comparator circuit 38, a current loop control circuit 40, and a voltage loop control circuit 42. Specifically, the acceleration circuit 36 is configured to determine a target (I_{DC-TGT}) of the DC current I_{DC} based on the target voltage V_{TGT}, the comparator circuit 38 is configured to generate a DC current differential (ΔI_{DC}) between the target (I_{DC-TGT}) of the DC current I_{DC} and the actual DC current I_{DC} indicated by the feedback signal 30, and the current loop control circuit 40 is configured to generate the acceleration current I_{ACCT} based on the determined DC current differential ΔI_{DC}. The voltage loop control circuit 42, on the other hand, is configured to generate the DC target voltage V_{DC-TGT} based on the target voltage V_{TGT}. In an embodiment, the current loop control circuit 40 may determine not to generate the acceleration current I_{ACCT} when the determined DC current differential ΔI_{DC} is smaller than a predefined current threshold.

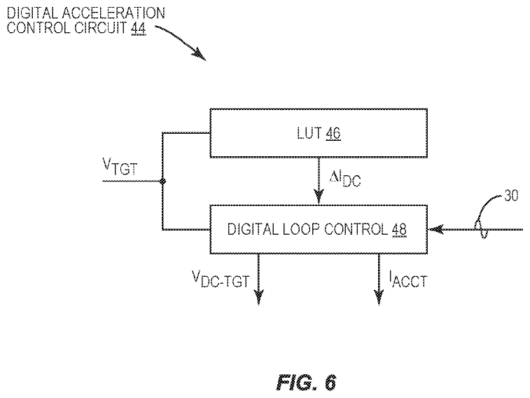

In another embodiment, the acceleration control circuit 16 in FIG. 2 can be implemented as a digital acceleration control circuit. In this regard, FIG. 6 is a schematic diagram of an exemplary analog acceleration control circuit 44 that can function as the acceleration control circuit 16 in the PMIC 12 in FIG. 2. Common elements between FIGS. 2 and 6 are shown therein with common element numbers and will not be re-described herein.

Herein, the digital acceleration control circuit 44 includes a lookup table (LUT) 46 and a digital loop control circuit 48. The LUT 46 may be configured to correlate a respective DC current target I_{DC-TGT} with different values of the target voltage V_{TGT}. The digital loop control circuit 48 is configured to receive the target voltage V_{TGT} from the transceiver circuit 18. The digital loop control circuit 48 is also configured to receive the feedback signal 30 that indicates the DC current I_{DC} and the DC voltage V_{DC}. The digital loop control circuit 48 can thus retrieve a respective DC current target I_{DC-TGT} from the LUT 46 based on the received target voltage V_{TGT}. Accordingly, the digital loop control circuit 48 can determine a DC current differential ΔI_{DC} between the respective DC current target I_{DC-TGT} and the DC current I_{DC} indicated in the feedback signal 30. The digital loop control circuit 48 can then generate the acceleration current ACCT based on the determined DC current differential ΔI_{DC} and generate the DC target voltage V_{DC-TGT} based on the target voltage V_{TGT}. In an embodiment, the digital loop control circuit 48 may determine not to generate the acceleration current I_{ACCT} when the determined DC current differential ΔI_{DC} is smaller than the predefined current threshold.

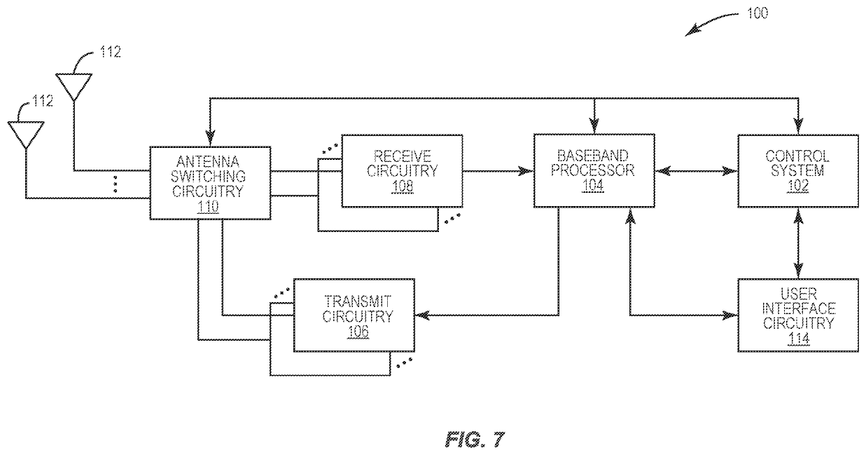

The wireless communication circuit 10 of FIG. 2 can be provided in a user element to support intra-symbol voltage change acceleration according to embodiments described above. In this regard, FIG. 7 is a schematic diagram of an exemplary user element 100 wherein the wireless communication circuit 10 of FIG. 2 can be provided.

Herein, the user element 100 can be any type of user elements, such as mobile terminals, smart watches, tablets, computers, navigation devices, access points, and like wireless communication devices that support wireless communications, such as cellular, wireless local area network (WLAN), Bluetooth, and near field communications. The user element 100 will generally include a control system 102, a baseband processor 104, transmit circuitry 106, receive circuitry 108, antenna switching circuitry 110, multiple antennas 112, and user interface circuitry 114. In a non-limiting example, the control system 102 can be a field-programmable gate array (FPGA), as an example. In this regard, the control system 102 can include at least a microprocessor(s), an embedded memory circuit(s), and a communication bus interface(s). The receive circuitry 108 receives radio frequency signals via the antennas 112 and through the antenna switching circuitry 110 from one or more base stations. A low noise amplifier and a filter cooperate to amplify and remove broadband interference from the received signal for processing. Downconversion and digitization circuitry (not shown) will then downconvert the filtered, received signal to an intermediate or baseband frequency signal, which is then digitized into one or more digital streams using analog-to-digital converter(s) (ADC).

The baseband processor 104 processes the digitized received signal to extract the information or data bits conveyed in the received signal. This processing typically comprises demodulation, decoding, and error correction operations, as will be discussed in greater detail below. The baseband processor 104 is generally implemented in one or more digital signal processors (DSPs) and application specific integrated circuits (ASICs).

For transmission, the baseband processor 104 receives digitized data, which may represent voice, data, or control information, from the control system 102, which it encodes for transmission. The encoded data is output to the transmit circuitry 106, where a digital-to-analog converter(s) (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission, and deliver the modulated carrier signal to the antennas 112 through the antenna switching circuitry 110. The multiple antennas 112 and the replicated transmit and receive circuitries 106, 108 may provide spatial diversity. Modulation and processing details will be understood by those skilled in the art.

Those skilled in the art will recognize improvements and modifications to the preferred embodiments of the present disclosure. All such improvements and modifications are considered within the scope of the concepts disclosed herein and the claims that follow.

1. A power management integrated circuit (PMIC), comprising:
a voltage modulation circuit configured to generate a voltage in a plurality of voltage modulation intervals; and
an acceleration control circuit configured to:
determine that the voltage is transitioning from a present voltage level in a present voltage modulation interval among the plurality of voltage modulation intervals to a future voltage level in a future voltage modulation interval immediately succeeding the present voltage modulation interval among the plurality of voltage modulation intervals; and
provide an acceleration current in a selected polarity to the voltage modulation circuit to thereby cause the voltage to transition from the present voltage level to the future voltage level within a voltage transition interval between the present voltage modulation interval and the future voltage modulation interval.

2. The PMIC of claim 1, wherein:
each of the plurality of voltage modulation intervals corresponds to a respective one of a plurality of orthogonal frequency division multiplexing, OFDM, symbols; and
the voltage transition interval corresponds to a cyclic prefix, CP, in each of the plurality of the OFDM symbols.

3. The PMIC of claim 1, wherein:
each of the plurality of voltage modulation intervals corresponds to a respective one of a plurality of timeslots each comprising a plurality of orthogonal frequency division multiplexing, OFDM, symbols; and
the voltage transition interval corresponds to an extended cyclic prefix located between each consecutive pair of the plurality of timeslots.

4. The PMIC of claim 1, wherein the voltage modulation circuit is further configured to generate the voltage as an average power tracking (APT) voltage.

5. The PMIC of claim 1, wherein the voltage modulation circuit comprises:
a direct-current (DC) voltage circuit configured to generate a DC voltage in each of the plurality of voltage modulation intervals based on a DC target voltage; and
an inductor-capacitor (LC) circuit comprising:
an output inductor configured to induce a DC current in each of the plurality of voltage modulation intervals based on the DC voltage; and
an output capacitor configured to modulate the voltage in each of the plurality of voltage modulation intervals based on the DC current.

6. The PMIC of claim 5, wherein the acceleration control circuit is further configured to:
receive a target voltage indicating the future voltage level in the future voltage modulation interval among the plurality of voltage modulation intervals; and
generate the DC target voltage based on the received target voltage.

7. The PMIC of claim 6, wherein the acceleration control circuit is further configured to:
receive a feedback signal indicating the DC current and the DC voltage; and
generate the acceleration current in the selected polarity based on the feedback signal and the target voltage V_{TGT}.

8. The PMIC of claim 7, wherein the acceleration control circuit is further configured to:
generate the acceleration current in a positive polarity when the future voltage level is higher than the present voltage level; and
generate the acceleration current in a negative polarity when the future voltage level is lower than the present voltage level.

9. The PMIC of claim 7, wherein the acceleration control circuit is further configured not to generate the acceleration current when a difference between the present voltage level and the future voltage level is smaller than a defined threshold.

10. The PMIC of claim 7, wherein the acceleration control circuit comprises:
an acceleration circuit configured to determine a target of the DC current based on the target voltage;
a comparator circuit configured to generate a DC current differential between the target of the DC current and the DC current indicated by the feedback signal;
a current loop control circuit configured to generate the acceleration current based on the determined DC current differential; and
a voltage loop control circuit configured to generate the DC target voltage based on the target voltage.

11. The PMIC of claim 7, wherein the acceleration control circuit comprises:
a lookup table (LUT) configured to correlate a respective DC current target with different values of the target voltage; and
a digital loop control circuit configured to:
receive the target voltage and the feedback signal indicating the DC current and the DC voltage;
retrieve the respective DC current target from the LUT corresponding to the received target voltage;
determine a DC current differential between the respective DC current target and the DC current indicated in the feedback signal;
generate the acceleration current based on the determined DC current differential; and
generate the DC target voltage based on the target voltage.

12. A wireless communication circuit comprising:
a power management integrated circuit (PMIC) comprising:
a voltage modulation circuit configured to generate a voltage in a plurality of voltage modulation intervals; and
an acceleration control circuit configured to:
determine that the voltage is transitioning from a present voltage level in a present voltage modulation interval among the plurality of voltage modulation intervals to a future voltage level in a future voltage modulation interval immediately succeeding the present voltage modulation interval among the plurality of voltage modulation intervals; and
provide an acceleration current in a selected polarity to the voltage modulation circuit to thereby cause the voltage to transition from the present voltage level to the future voltage level within a voltage transition interval between the present voltage modulation interval and the future voltage modulation interval.

13. The wireless communication circuit of claim 12, wherein:
each of the plurality of voltage modulation intervals corresponds to a respective one of a plurality of orthogonal frequency division multiplexing (OFDM) symbols; and
the voltage transition interval corresponds to a cyclic prefix (CP) in each of the plurality of the OFDM symbols.

14. The wireless communication circuit of claim 12, wherein:
each of the plurality of voltage modulation intervals corresponds to a respective one of a plurality of timeslots each comprising a plurality of orthogonal frequency division multiplexing, OFDM, symbols; and
the voltage transition interval corresponds to an extended cyclic prefix (ECP) located between each consecutive pair of the plurality of timeslots.

15. The wireless communication circuit of claim 12, wherein the voltage modulation circuit is further configured to generate the voltage as an average power tracking (APT) voltage.

16. The wireless communication circuit of claim 12, wherein the acceleration control circuit is further configured to:
generate the acceleration current in a positive polarity when the future voltage level is higher than the present voltage level; and
generate the acceleration current in a negative polarity when the future voltage level is lower than the present voltage level.

17. The wireless communication circuit of claim 12, wherein the acceleration control circuit is further configured not to generate the acceleration current when a difference between the present voltage level and the future voltage level is smaller than a defined threshold.

18. The wireless communication circuit of claim 12, further comprising:
a power amplifier circuit coupled to the PMIC and configured to amplify a radio frequency (RF) signal in each of the plurality of voltage modulation intervals based on the voltage; and
a transceiver circuit configured to:
generate and provide the RF signal to the power amplifier circuit;
generate a respective target voltage for each of the plurality of voltage modulation intervals; and
provide the target voltage to the acceleration control circuit.

19. The wireless communication circuit of claim 18, wherein the transceiver circuit is further configured to:
generate a digital word indicating the respective target voltage for each of the plurality of voltage modulation intervals; and
provide the digital word to the acceleration control circuit over an RF frontend (RFFE) interface.

20. The wireless communication circuit of claim 19, wherein the transceiver circuit is further configured to provide the digital word for a respective one of the plurality of voltage modulation intervals to the acceleration control circuit prior to a start of the respective one of the plurality of voltage modulation intervals.
